(19) United States
(12) Patent Application Publication
(10) Pub. No.: US 2026/0082661 A1
(43) Pub. Date: Mar. 19, 2026

(54) SEMICONDUCTOR STRUCTURE AND METHOD FOR FORMING THE SAME

(71) Applicant: Shanghai GTX Semiconductor Co., Ltd., Shanghai (CN)

(72) Inventor: Shuhui HU, Shanghai (CN)

(21) Appl. No.: 19/324,238

(22) Filed: Sep. 10, 2025

(30) Foreign Application Priority Data
Sep. 14, 2024 (CN) 202411299401.1

(51) Int. Cl. H10D 64/27; C23C 14/22; H10D 30/01; H10D 30/62

(52) U.S. Cl. CPC H10D 64/513; C23C 14/228; H10D 30/024; H10D 30/62; H10D 64/514

(57) ABSTRACT

The present disclosure provides a semiconductor structure and a method for forming the same. The method includes: providing a substrate having a metal gate trench with a work function layer on the bottom and sidewalls of the metal gate trench; forming a diffusion barrier layer on the work function layer, including: performing a physical vapor deposition process with a negative bias power less than a preset power to form a first diffusion barrier sublayer on the work function layer at the bottom of the metal gate trench. The present disclosure can reduce the possibility of premature sealing.

This application claims the priority to Chinese Patent Application No. 202411299401.1, filed on Sep. 14, 2024, which is incorporated herein by reference in its entirety.

### FIELD

The present disclosure relates to the technical field of semiconductors, and in particular, to a semiconductor structure and a method for forming the same.

### BACKGROUND

With the development of semiconductor technology, the integration level of semiconductor devices continues to increase, and the critical dimension (CD) of semiconductor devices becomes smaller and smaller, which puts forward higher requirements for the performance of devices such as transistors. Due to the relatively large resistance of the polysilicon gate, in the prior art, metal materials are increasingly being used as the gate in the transistors. By using a metal gate (MG) with a lower resistance, it is helpful to improve the performance of the devices.

However, in the prior art, due to the limitation of the critical dimension and the layer-by-layer stacking of the thin films for filling the metal gate, the critical dimension becomes smaller and smaller during the filling of the metal material. Consequently, the process window for filling the metal material becomes smaller and smaller, resulting in the ineffective filling of the metal material and the formation of void defects, which affects the electrical performance of the metal gate.

### SUMMARY

Embodiments of the present disclosure provides a method for forming a semiconductor structure, including: providing a substrate having a metal gate trench, wherein a bottom and sidewalls of the metal gate trench are provided with a work function layer; forming a diffusion barrier layer on the work function layer, including: forming a first diffusion barrier sublayer via a physical vapor deposition process with a negative bias power less than a preset power to form a first diffusion barrier sublayer on the work function layer at the bottom of the metal gate trench; and forming a second diffusion barrier sublayer covering the sidewalls of the metal gate trench and the first diffusion barrier sublayer.

Embodiments of the present disclosure provides a semiconductor structure, including: a substrate having a metal gate trench; a work function layer covering the bottom and sidewalls of the metal gate trench; a diffusion barrier layer including a first diffusion barrier sublayer and a second diffusion barrier sublayer, wherein the first diffusion barrier sublayer is located on the work function layer at the bottom of the metal gate trench, and the second diffusion barrier sublayer covers the sidewalls of the metal gate trench and the first diffusion barrier sublayer.

### BRIEF DESCRIPTION OF DRAWINGS

FIG. 1 is a schematic cross-sectional structure diagram of a device with a metal gate in the prior art;

FIG. 2 is a flowchart of a method for forming a semiconductor structure according to embodiments of the present disclosure;

FIG. 3 to FIG. 6 are schematic cross-sectional structure diagrams of the device corresponding to each step in the method for forming a semiconductor structure according to embodiments of the present disclosure;

FIG. 7 is a schematic diagram of a relationship curve between voltage and nitrogen flow rate according to embodiments of the present disclosure.

Explanation of reference signs in the drawings:

Substrate 100, metal gate trench 101, work function layer 110, diffusion barrier layer 120, wetting layer 130, metal material 140, void 141, substrate 200, metal gate trench 201, sidewall 202, work function layer 210, interface layer 211, gate dielectric layer 212, first work function sublayer 2101, second work function sublayer 2102, third work function sublayer 2103, diffusion barrier layer 220, first diffusion barrier sublayer 2201, second diffusion barrier sublayer 2202, wetting layer 230, metal material 240.

### DETAILED DESCRIPTION

As mentioned above, in the prior art, due to the limitation of the critical dimension and the layer-by-layer stacking of the thin films for filling the metal gate, the critical dimension becomes smaller and smaller during the filling of the metal material. As a result, the process window for filling the metal material becomes smaller and smaller, making it impossible for the metal material to be effectively filled, resulting in void defects.

Through research, it has been found that an important step in forming the metal gate is to form a diffusion barrier layer to reduce the diffusion of metal atoms from the metal gate into the work function layer. In the prior art, the prepared diffusion barrier layer will laterally overhang at the top of the metal gate trench. In severe cases, it is likely to cause the problem of premature sealing during the filling of the metal material.

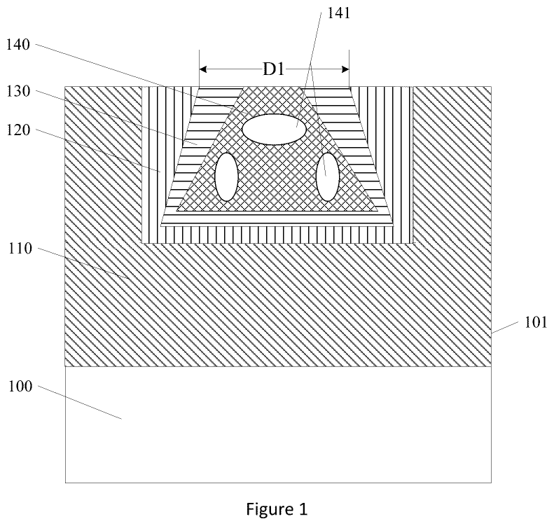

With reference to FIG. 1, FIG. 1 is a schematic cross-sectional structure diagram of a device with a metal gate in the prior art. As shown in FIG. 1, a substrate 100 is provided. The substrate 100 has a metal gate trench 101. The bottom and sidewalls of the metal gate trench 101 are provided with a work function layer 110, and a diffusion barrier layer 120 is formed on the work function layer 110. Through further research, it has been found that the diffusion barrier layer 120 formed at the top corners of the metal gate trench 101 grows rapidly and approaches each other laterally. As a result, after the diffusion barrier layer 120 is formed, the opening size D1 at the top of the metal gate trench 101 is relatively small. Consequently, other material layers formed subsequently (such as the wetting layer 130) have the problem of lateral overhang, further reducing the opening size at the top of the metal gate trench 101. On this basis, when filling a metal material 140, the problem of premature sealing is likely to occur. As shown in FIG. 1, the metal material 140 is prematurely sealed at the top of the metal gate trench 101, resulting in the formation of a hole 141, which seriously affects the electrical performance of the metal gate. For example, it leads to a relatively large resistance of the metal gate, failing to meet the requirements.

In the embodiments of the present disclosure, a physical vapor deposition (PVD) process is employed to form a first diffusion barrier sublayer under the condition that the negative bias power is less than a predetermined power (e.g., less than 100 W). Due to the relatively low negative bias power, it is more conducive to depositing the first diffusion barrier sublayer on the work function layer at the bottom of the metal gate trench while reducing the deposition amount on the sidewall surfaces of the metal gate trench. In practical applications, for example, the negative bias power can be controlled to be less than 100 W, so that only a small amount or even almost none of the first diffusion barrier sublayer is formed on the sidewall surfaces of the metal gate trench. That is to say, the first diffusion barrier sublayer can be controlled to be formed almost entirely on the work function layer at the bottom of the metal gate trench. This effectively avoids the lateral overhang problem of the first diffusion barrier sublayer at the top of the metal gate trench, reduces the possibility of premature sealing, and effectively improves the electrical performance of the metal gate. Moreover, Because the main function of the diffusion barrier layer is to reduce the vertical diffusion of metal atoms from the metal gate into the underlying work function layer, forming the first diffusion barrier sublayer at the bottom of the metal gate trench can already provide an effective blocking effect while mitigating the lateral overhang problem.

In order to make the above-mentioned objectives, features and beneficial effects of the present disclosure more obvious and understandable, the specific embodiments of the present disclosure will be described in detail below in conjunction with the accompanying drawings.

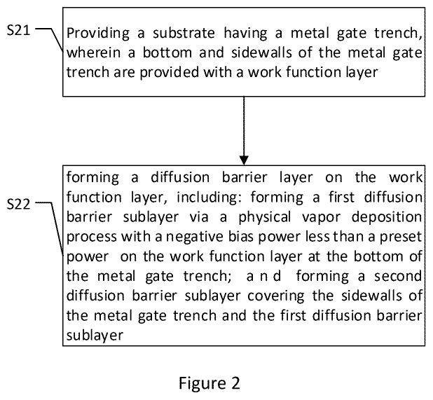

With reference to FIG. 2, FIG. 2 is a flowchart of a method for forming a semiconductor structure according to embodiments of the present disclosure. The method for forming a semiconductor structure may include Steps S21 to S22.

In step S21, a substrate is provided. The substrate has a metal gate trench, and the bottom and sidewalls of the metal gate trench are provided with a work function layer.

In step S22, a diffusion barrier layer is formed on the work function layer, including: performing a PVD process with a negative bias power less than a preset power to form a first diffusion barrier sublayer on the work function layer at the bottom of the metal gate trench.

The following is an explanation of each of the above steps.

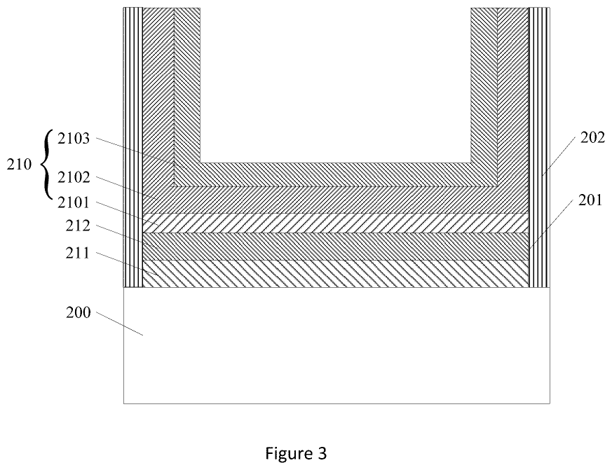

FIGS. 3 to 6 are schematic cross-sectional structure diagrams of the device corresponding to each step in the method for forming a semiconductor structure according to the embodiments of the present disclosure.

With reference to FIG. 3, a substrate 200 is provided. The substrate 200 has a metal gate trench 201, and the bottom and sidewalls of the metal gate trench 201 are provided with a work function layer 210.

The substrate 200 may include a semiconductor substrate. The metal gate trench 201 may be formed by using polysilicon to form a dummy gate structure on the semiconductor substrate, forming spacers 202 on both sides of the dummy gate structure, and then removing the dummy gate structure inside the spacers 202.

In some embodiments, the semiconductor substrate may be a silicon substrate. In other embodiments, the material of the semiconductor substrate may be germanium, silicon germanide, silicon carbide, gallium arsenide, or indium gallium. The semiconductor substrate may be a silicon-on-insulator substrate or a germanium-on-insulator substrate. The semiconductor substrate may have other appropriate structures. For example, the semiconductor device is a fin field-effect transistor, the semiconductor substrate may have fins. However, the solution of the embodiments of the present disclosure is not limited thereto, and the semiconductor device may be other semiconductor devices.

It should be noted that in some embodiments, other appropriate material layers may be formed before forming the work function layer on the bottom and sidewalls of the metal gate trench. The embodiment of the present disclosure does not impose any limitations on whether there are other material layers between the substrate 200 and the work function layer 210.

For example, an interface layer 211 and a gate dielectric layer 212 are further formed between the substrate 200 and the work function layer 210. Specifically, the material of the interface layer (IL) 211 may be SiON, also known as nitrogen-doped silicon oxide. The material of the gate dielectric layer 212 may be a high dielectric constant (High-K, HK) material layer, such as an HK dielectric layer. The material of the gate dielectric layer 212 may be a combination selected from one or more of the following: hafnium oxide (HfO₂), titanium oxide (TiO₂2), tantalum pentoxide (Ta₂O₅), and zirconium oxide (ZrO₂).

In some embodiments, the work function layer 210 may be a stacked structure of multiple material layers, which can be used to adjust the electrical properties of the metal gate, thereby affecting the performance of the device, such as electrical property like the threshold voltage (Vt) and saturation drain current (Idsat) of the transistor.

In some embodiments shown in FIG. 3, the work function layer 210 may include one or more of the following: a first work function sublayer 2101, a second work function sublayer 2102, and a third work function sublayer 2103.

The material of the first work function sublayer 2101 may be titanium nitride (TiN).

The material of the second work function sublayer 2102 may be tantalum nitride (TaN).

The third work function sublayer 2103 can be specifically selected according to the device type. For example, for the metal gate of an N-type metal oxide semiconductor (NMOS) device, the material of the third work function sublayer 2103 may be titanium aluminum (TiAl); for the metal gate of a P-type metal oxide semiconductor (PMOS) device, the material of the third work function sublayer 2103 may be titanium nitride (TiN).

The thicknesses of the first work function sublayer 2101, the second work function sublayer 2102, and the third work function sublayer 2103 may all be less than 100 angstroms. In some embodiments, they can be formed by an atomic layer deposition (ALD) process.

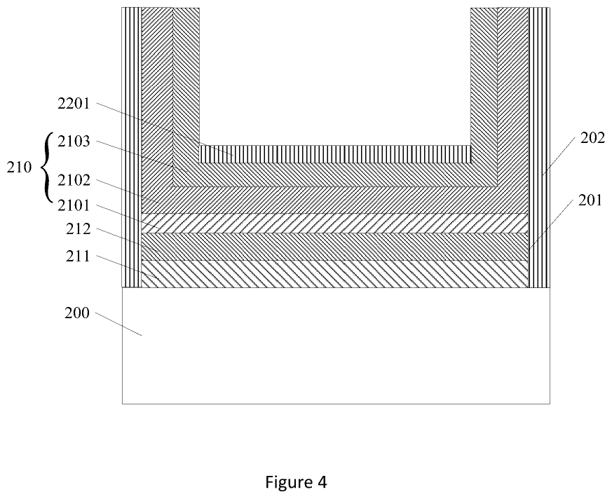

With reference to FIG. 4, a diffusion barrier layer is formed on the work function layer 210. The step of forming the diffusion barrier layer on the work function layer may include: performing a PVD process with a negative bias power less than a preset power to form a first diffusion barrier sublayer 2201 on the work function layer at the bottom of the metal gate trench.

In other words, the first diffusion barrier sublayer 2201 is formed by a PVD process with a negative bias power less than a preset power. The lower the negative bias power, the more concentrated the direction of ion deposition becomes (e.g., closer to vertical deposition), allowing the first diffusion barrier sublayer 2201 to be almost entirely formed on the work function layer 210 at the bottom of the metal gate trench 201. For example, the thickness of the first diffusion barrier sublayer formed at the bottom of the metal gate trench may be 4 nm to 7 nm, while the thickness covering the sidewalls of the metal gate trench may be only 0 to 0.5 nm. By further reducing the negative bias power, the thickness of the first diffusion barrier sublayer covering the sidewalls of the metal gate trench in the first diffusion barrier sublayer can be nearly zero, that is, almost no material from the first diffusion barrier sublayer is formed on the sidewall surfaces of the metal gate trench.

The physical vapor deposition (PVD) technology involves using physical methods under vacuum conditions to vaporize the surface of a material source (solid or liquid) into gaseous atoms or molecules, or partially ionize them into ions. Through a low-pressure gas (or plasma) process, a thin film is deposited on the substrate surface. In some embodiments, an inert gas (such as argon, Ar) can be ionized to bombard a target (such as a titanium target). The bombarded titanium reacts with dissociated N₂ to form a first diffusion barrier sublayer 2201 containing TiN.

In embodiments of the present disclosure, a patterned mask layer (not shown) can be formed on the substrate 200. The patterned mask layer exposes the area to be deposited. Then, a PVD process is performed to ionize the surface of the target material into ions, and a material thin film is deposited through a plasma deposition process. The process parameters may include negative bias power (AC Power) and direct current power (DC Power).

The chamber gas (such as one or more of argon and nitrogen) in the PVD process chamber can be dissociated under the action of DC power, and then bombard the target to obtain the ions to be deposited. Under the action of negative bias power, the ions to be deposited react with the chamber gas in the PVD process chamber and then deposit on the bottom of chamber. It should be noted that the smaller the negative bias power, the more concentrated the deposition direction of the ions to be deposited, for example, the ions to be deposited closer to vertical fall. After removing the patterned mask layer, the first diffusion barrier sublayer 2201 is almost entirely located on the work function layer 210 at the bottom of the metal gate trench 201. Correspondingly, the greater the negative bias power, the more dispersed the deposition direction of the ions to be deposited, so that the formed first diffusion barrier sublayer 2201 is not only located on the work function layer 210 at the bottom of the metal gate trench 201, but also on the sidewall surface of the metal gate trench 201.

In some embodiments, the negative bias power is less than a preset power, which may be less or equal to 100 W. In further embodiments, the preset power may be further reduced to less or equal to 50 W. In some embodiments, the negative bias power can be set to 0, theoretically ensuring that the entire first diffusion barrier sublayer 2201 is formed exclusively on the work function layer 210 at the bottom of the metal gate trench 201.

In addition, the greater the DC power, the greater the number of dissociated ions. Correspondingly, the smaller the DC power, the smaller the number of dissociated ions.

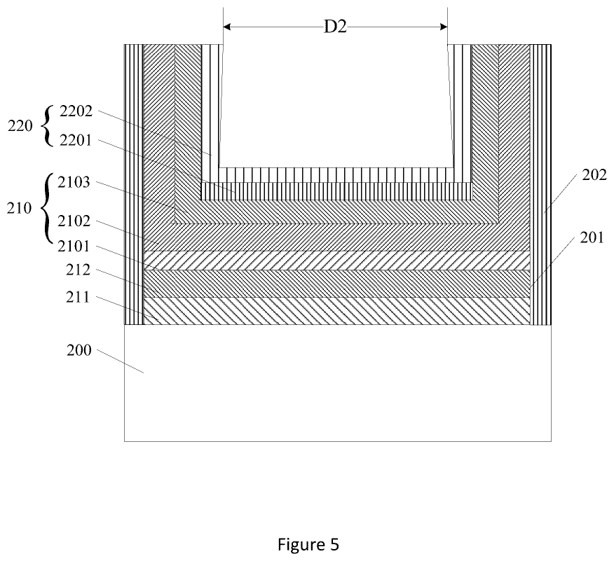

With reference to FIG. 5, the step of forming the diffusion barrier layer may further include forming a second diffusion barrier sublayer 2202. When the process duration for forming the first diffusion barrier sublayer 2201 reaches a preset process duration, the process gas can be adjusted, for example, reducing the flow rate of N₂ from a first gas flow rate to a second gas flow rate, to form a second diffusion barrier sublayer 2202 containing a nitride material. It can be understood that the diffusion barrier layer 220 in the embodiment of the present disclosure includes the first diffusion barrier sublayer 2201 and the second diffusion barrier sublayer 2202.

In some embodiments, the material of the first diffusion barrier sublayer 2201 is TiN, and the reactive gas for the first diffusion barrier sublayer 2201 contains N₂ at a first gas flow rate. Therefore, the material of the second diffusion barrier sublayer 2202 may also include TiN. It should be noted that a higher N₂ gas flow rate can be referred to as a nitrogen-rich mode, in which the TiN in the first diffusion barrier sublayer 2201 tends to have a higher N content and a relatively lower Ti content. Conversely, a lower N₂ gas flow rate can be referred to as a titanium-rich mode, in which the TiN in the second diffusion barrier sublayer 2202 tends to have a lower N content and a relatively higher Ti content.

In the embodiment of the present disclosure, when the first diffusion barrier sublayer 2201 is a TiN layer and the reactive gas for the first diffusion barrier sublayer contains N₂ at a first gas flow rate, upon the process duration for forming the first diffusion barrier sublayer 2201 reaching a preset process duration, the first gas flow rate is reduced to a second gas flow rate to form a second diffusion barrier sublayer 2202. Here, the first gas flow rate is greater than the second gas flow rate. As a result, the second diffusion barrier sublayer 2202 can be formed on the first diffusion barrier sublayer 2201. Because the TiN in the first diffusion barrier sublayer 2201 formed in the nitrogen-rich mode tends to have a higher N content and a relatively lower Ti content, it can have a relatively stronger blocking ability, thereby further enhancing the blocking effect of the first diffusion barrier sublayer 2201. Because the TiN in the second diffusion barrier sublayer 2202 formed in the titanium-rich mode tends to have a lower N content and a relatively higher Ti content, it can have relatively stronger sidewall adsorption and diffusion capabilities. Therefore, the second diffusion barrier sublayer 2202 can serve as an effective supplement to the first diffusion barrier sublayer 2201.

In some embodiments, the subsequent process includes a Ti deposition step. Employing a titanium-rich mode for the second diffusion barrier sublayer 2202 can prevent the consumption and diffusion of Ti during subsequent deposition processes, which provides a buffer layer for Ti in advance, reducing the subsequent Ti consumption and ensuring an adequate amount of Ti remains to form a wetting layer for subsequent metal (e.g., Al) filling processes.

Further, the method for forming the second diffusion barrier sublayer 2202 may further include: performing a PVD process with a negative bias power selected from a range of 200 W to 600 W, so that the second diffusion barrier sublayer 2202 is formed on the work function layer 210 on the sidewalls of the metal gate trench 201 and on the first diffusion barrier sublayer 2201 at the bottom of the metal gate trench 201. In other words, the formation process of the second diffusion barrier sublayer 2202 may be a PVD process with a negative bias power selected from the range of 200 W to 600 W, so that the second diffusion barrier sublayer 2202 is located on the work function layer 210 on the sidewalls of the metal gate trench 201 and on the first diffusion barrier sublayer 2201 at the bottom of the metal gate trench 201.

It should be noted that in the embodiments of the present disclosure, the negative bias power should not be too high. Excessively high negative bias power will cause overly severe back-sputtering of the material (such as TiN) of the first diffusion barrier sublayer 2201 at the bottom, resulting in significant overhang. In the embodiments of the present disclosure, the negative bias power should not be too low, if the negative bias power is too low, the formation position of the second diffusion barrier sublayer 2202 will be too close to that of the first diffusion barrier sublayer 2201, making it difficult to achieve the adsorption and diffusion effects on the sidewalls.

In the embodiments of the present disclosure, the second diffusion barrier sublayer 2202 is formed through a PVD process with a negative bias power selected from a range of 200 W to 600 W. Because the negative bias power applied during the formation of the second diffusion barrier sublayer 2202 is higher than that used for the first diffusion barrier sublayer 2201, the second diffusion barrier sublayer 2202 can be deposited not only on the bottom of the metal gate trench 201 but also on its sidewalls. Consequently, while effectively complementing the first diffusion barrier sublayer 2201 at the bottom, the second diffusion barrier sublayer 2202 also provides isolation between the work function layer 210 and subsequent material layers (such as a wetting layer) formed on the sidewalls of the metal gate trench, which prevents reactions between the wetting layer and the work function layer 210, thereby avoiding potential degradation of device performance.

It should be noted that because the formed first diffusion barrier sublayer 2201 is almost entirely located on the work function layer 210 at the bottom of the metal gate trench 201, the problem of lateral overhang of the first diffusion barrier sublayer 2201 at the top of the metal gate trench 201 has been effectively avoided. Therefore, a favorable sidewall foundation is provided for the formation of the second diffusion barrier sublayer 2202, effectively reducing the lateral overhang problem of the formed second diffusion barrier sublayer 2202. As shown in FIG. 5, the top distance D2 of the opening formed by the second diffusion barrier sublayer 2202 is smaller than the top distance D1 of the opening formed by the diffusion barrier layer 120 shown in FIG. 1.

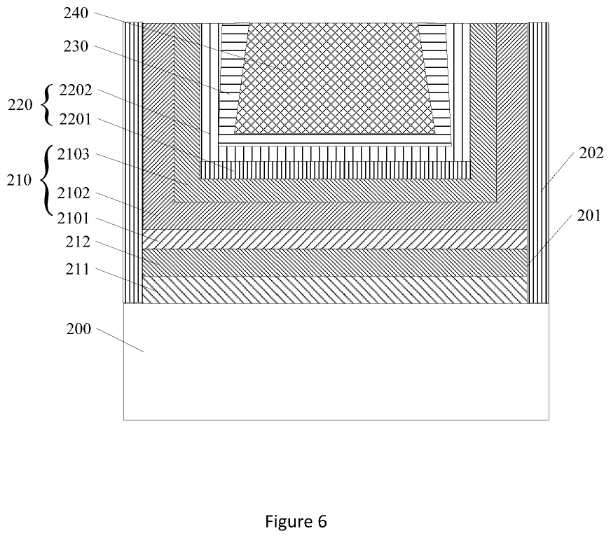

With reference to FIG. 6, a wetting layer 230 may be formed, which is positioned on the second diffusion barrier sublayer 2202 on the sidewalls of the metal gate trench 201 and on the second diffusion barrier sublayer 2202 at the bottom of the metal gate trench 201; a metal material 240 may be filled into the trench formed by the wetting layer 230.

The wetting layer 230 serves as a foundation for the reflow of the metal material 240, effectively preventing agglomeration of the metal material 240 and enhancing its compactness and bonding strength.

In the embodiment of the present disclosure, because the formed first diffusion barrier sublayer 2201 is almost entirely located at the bottom of the metal gate trench 201, it effectively avoids the lateral overhang of the work function layer 210 at the top of the metal gate trench 201. This provides a favorable sidewall foundation for the formation of the wetting layer 230, thereby correspondingly reducing the lateral overhang of the formed wetting layer 230.

In some embodiments, the wetting layer 230 includes a Ti layer. It should be noted that due to the Ti-containing material of the wetting layer 230, Ti consumption is prone to occur in practical applications, leading to insufficient wetting effect. In this embodiment, the wetting layer 230 is formed on the second diffusion barrier sublayer 2202, which may be a Ti-rich layer, effectively reducing the consumption of Ti in the wetting layer 230.

With reference back to FIG. 2, in some embodiments, when the deposition of the first diffusion barrier sublayer for a preset process duration, the first gas flow rate is reduced to the second gas flow rate to form the second diffusion barrier sublayer. The method for determining the preset process duration may include: providing a plurality of sample substrates; respectively forming the first diffusion barrier sublayer on the plurality of sample substrates with different process durations; respectively measuring the thicknesses of the formed first diffusion barrier sublayers, and taking the process duration corresponding to the first diffusion barrier sublayer with a preset thickness as the preset process duration. In this way, a more accurate preset process duration can be determined through sample testing.

Further, the preset thickness of the first diffusion barrier sublayer at the bottom of the metal gate trench may be 0.6 to 0.7 times the total thickness of the diffusion barrier layer.

In some embodiments, before taking the process duration corresponding to the first diffusion barrier sublayer with the preset thickness as the preset process duration, the method may further include: determining the standard value of the total thickness of the diffusion barrier layer in the standard process of the semiconductor structure; determining the preset thickness according to the preset ratio between the preset thickness and the standard value of the total thickness, where the preset ratio is selected from 0.6 to 0.7.

In some embodiments, the preset thickness may be 4 nm to 7 nm, such as 5 nm to 6 nm, for example, 5.5 nm.

In embodiments of the present disclosure, setting the preset thickness of the first diffusion barrier sublayer to 0.6 to 0.7 times the total thickness of the diffusion barrier layer means that, for a diffusion barrier layer with a certain thickness, it is divided into the first and second diffusion barrier sublayers in this embodiment. The total thickness of the first and second diffusion barrier sublayers at the bottom of the metal gate trench meets the expected thickness to satisfy the requirement of blocking metal atom diffusion vertically, while the thickness of the second diffusion barrier sublayer on the sidewalls of the metal gate trench is controlled to meet the requirement of blocking metal atom diffusion laterally.

More specifically, by determining the standard value of the total thickness of the diffusion barrier layer in the standard process of the semiconductor structure and calculating the preset thickness based on the preset ratio between the preset thickness and the standard value where the preset ratio is selected from 0.6 to 0.7, the accurate thickness of the first diffusion barrier sublayer can be effectively determined by using the standard parameter of the total thickness standard value, as well as quantifiable and pre-set parameters such as the preset thickness and preset ratio.

Furthermore, the sample substrate may be a bare wafer; or the sample substrate may include a bare wafer and a dielectric layer located on the bare wafer.

A bare wafer which is also known as a monitor wafer can be regarded as a semiconductor substrate without artificial processing.

The dielectric layer which is also known as an insulating layer may be a stacked layer of one or more of the following: an oxide layer and a nitride layer.

The oxide layer may be formed by a thermal oxidation process, and its specific material is determined according to the material of the semiconductor substrate. For instance, for a silicon substrate, the first oxide layer formed by the thermal oxidation process is silicon oxide (e.g., SiO₂); for a germanium substrate, it is germanium oxide, and so on.

In the embodiments of the present disclosure, using a bare wafer or a bare wafer with a dielectric layer as the sample substrate allows selecting materials closer to actual products for sample testing according to practical conditions, further improving the validity of the obtained data.

In some embodiments, appropriate methods may be used to measure the thickness of the first diffusion barrier sublayer on the sample substrate.

One or more of the following methods can be used to measure the thickness of the formed first diffusion barrier sublayer: probe profiler, X-ray fluorescence spectrometer, X-ray photoelectron spectrometer, and slicing analysis method.

The probe profiler (also known as a step profiler, abbreviated as KLA) provides high-precision 2D and 3D surface measurements, capable of measuring step height, surface roughness, warpage, and stress with excellent stability and reliability.

The X-ray fluorescence spectrometer (XRF) consists of an excitation source (X-ray tube) and a detection system. The X-ray tube generates incident X-rays (primary X-rays), which excite the sample to produce X-ray fluorescence (secondary X-rays). The detector then measures this X-ray fluorescence.

The X-ray Photoelectron Spectroscopy (XPS) is a quantitative spectroscopic technique used to measure the empirical chemical formula, chemical states, and electronic states of various elements in a material. While irradiating the material with an X-ray beam, the kinetic energy and the number of electrons escaping from a depth of 1 to 10 nanometers from the material surface are measured to obtain the X-ray photoelectron spectrum.

The slicing analysis method may involve slicing the sample substrate and the first diffusion barrier sublayer thereon, followed by measuring the slices using a scanning electron microscope (SEM) or other appropriate tools.

In the embodiments of the present disclosure, by measuring the thickness of the formed first diffusion barrier sublayer through appropriate methods, the thickness of the first diffusion barrier sublayer can be accurately obtained. Subsequently, by using the process duration corresponding to the first diffusion barrier sublayer with the preset thickness as the preset process duration, an accurate preset process duration can be determined. This enables reducing the first gas flow rate to that of the second gas flow rate at a more precise timing.

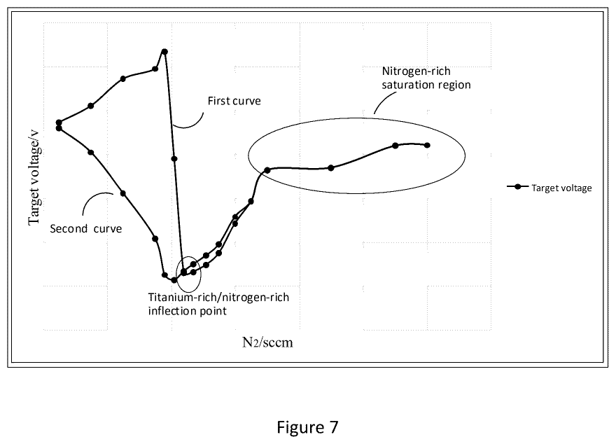

Referring to FIG. 7, which is a schematic diagram of a relationship curve between voltage and nitrogen flow rate in the embodiments of the present disclosure.

The voltage (also referred to as the target voltage) represents the DC voltage associated with the DC power, the unit of the voltage is volts (V).

The relationship curve of voltage with respect to nitrogen flow rate shown in FIG. 7 can be pre-obtained in the process chamber for forming the first diffusion barrier sublayer.

In some embodiments, before forming the first diffusion barrier sublayer on the work function layer, the method may further include: determining a relationship curve of voltage with respect to nitrogen gas flow rate, where the relationship curve includes a first curve and a second curve, the first curve representing the voltage corresponding to a process in which nitrogen flow rate is gradually increased from zero to a preset value, and the second curve representing the voltage corresponding to a process in which nitrogen flow rate is gradually decreased from the preset value to zero; determining an inflection point of the voltage based on the first curve; determining a minimum point greater than the inflection point among overlap points of the first curve and the second curve; wherein the first gas flow rate is greater than the nitrogen flow rate corresponding to the minimum point, and the second gas flow rate is less than the nitrogen flow rate corresponding to the inflection point.

In some embodiments, the curve model can be output by gradually increasing nitrogen flow rate from zero to a preset maximum value and then decreasing it back to zero.

By setting the first gas flow rate to be greater than the nitrogen flow rate corresponding to the minimum point, the first diffusion barrier sublayer can be formed with N₂ from the nitrogen-rich saturation region.

As shown in FIG. 7, as the gas flow rate of the nitrogen changes, the voltage curve exhibits a distinct inflection point, which can be referred to as the nitrogen-rich/titanium-rich inflection point. To the left of this inflection point in FIG. 7 is the titanium-rich mode, while to the right is the nitrogen-rich mode. The inflection point indicates the transition of the voltage change from a tendency to decrease to a tendency to increase. For example, the inflection point can be the lowest voltage point on the curve or derived from curve fitting.

In the first curve where the nitrogen flow rate is gradually increased from zero to the preset maximum value (also referred to as the N₂ increasing curve), the region to the right of the titanium-rich/nitrogen-rich inflection point is collectively referred to as the nitrogen-rich region. This nitrogen-rich region can be divided into a nitrogen-rich saturation region and a nitrogen-rich non-saturation region. The point where the standard voltage value during the gradual increase of N₂ coincides with the standard voltage value during the gradual decrease of N₂ (i.e., the minimum point, also known as the infinite approximation point) marks the starting position of the nitrogen-rich saturation region. The area to the right of this minimum point is the nitrogen-rich saturation region.

Therefore, in some embodiments of the present disclosure, it is only necessary to monitor the standard voltage and confirm the switch between the titanium-rich mode and the nitrogen-rich mode when the titanium-rich/nitrogen-rich inflection point is detected. Therefore, when reducing the first gas flow rate to the second gas flow rate, it is more conducive to switching from the nitrogen-rich mode under the first gas flow rate to the titanium-rich mode under the second gas flow rate. Certainly, in other optional examples, it is also possible to switch from a film layer with a higher nitrogen content formed under the first gas flow rate to a film layer with a lower nitrogen content under the second gas flow rate.

It should be noted that in the embodiments of the present disclosure, other appropriate methods may be used to distinguish between the nitrogen-rich saturation region and the nitrogen-rich non-saturation region. For example, a bias test (also known as a batch test) can be designed to measure the Ti/N ratio of the first diffusion barrier sublayer formed under different N₂ flow rates using XPS technology. When the N₂ flow rate reaches a certain level, it may be found that the Ti/N ratio no longer changes, indicating N saturation. In this case, the corresponding nitrogen flow rate is the starting position of the nitrogen-rich saturation region.

In some embodiments, the first gas flow rate may be selected from a range from 80 sccm to 120 sccm, such as from 90 sccm to 110 sccm, for example, 100 sccm.

In some embodiments, the second gas flow rate may be selected from a range from 20 sccm to 40 sccm, such as from 25 sccm to 35 sccm, for example, 30 sccm.

In the embodiments of the present disclosure, by adopting appropriate first and second gas flow rates, the barrier performance of the first diffusion barrier sublayer 2201 can be enhanced, while relatively stronger sidewall adsorption and diffusion capabilities can be achieved through the second diffusion barrier sublayer 2202. Additionally, embodiments of the present disclosure discloses a semiconductor structure, which, with reference to FIG. 6, may include: a substrate 200 having a metal gate trench 201, where the bottom and sidewalls of the metal gate trench 201 are provided with a work function layer 210; and a diffusion barrier layer including a first diffusion barrier sublayer 2201 positioned on the work function layer 210 at the bottom of the metal gate trench 201.

Further, the diffusion barrier layer may further include: a second diffusion barrier sublayer 2202, which is located on the work function layer 210 on the sidewalls of the metal gate trench 201 and on the first diffusion barrier sublayer 2201 at the bottom of the metal gate trench 201.

Further, both the first diffusion barrier sublayer 2201 and the second diffusion barrier sublayer 2202 may include nitride materials, and the nitrogen content in the first diffusion barrier sublayer 2201 is higher than that in the second diffusion barrier sublayer 2202.

Further, the first diffusion barrier sublayer 2201 may be a TiN layer; and/or the second diffusion barrier sublayer 2202 may be a TiN layer.

Further, the semiconductor structure may further include: a wetting layer 230 disposed on the second diffusion barrier sublayer 2202 on the sidewalls and the bottom of the metal gate trench 201; and a metal material 240 filling the metal gate trench formed with the wetting layer 230.

In embodiments of the present disclosure, by forming the first diffusion barrier sublayer 2201 almost entirely on the work function layer at the bottom of the metal gate trench 201, the lateral overhang problem of the first diffusion barrier sublayer 2201 at the top of the metal gate trench 201 is effectively avoided. This reduces the likelihood of premature sealing and effectively improves the electrical performance of the metal gate. Additionally, because the primary function of the first diffusion barrier sublayer 2201 is to reduce the vertical diffusion of metal atoms from the metal gate into the underlying work function layer 210, forming the first diffusion barrier sublayer 2201 at the bottom of the metal gate trench 201 can already provide an effective barrier while mitigating the lateral overhang problem.

It should be understood that the term “and/or” herein is merely used to describe the associative relationship of associated objects, indicating that three relationships may exist. For example, A and/or B may represent: A alone, both A and B simultaneously, or B alone. Additionally, the character “/” herein indicates that the associated objects before and after are in an “or” relationship. As used herein, unless explicitly stated otherwise, the term “or” covers all possible combinations unless infeasible. For example, if it is stated that a component may include A or B, then unless explicitly stated otherwise or infeasible, the component may include A, or B, or both A and B. As a second example, if it is stated that a component may include A, B, or C, then unless explicitly stated otherwise or infeasible, the component may include A, or B, or C, or A and B, or A and C, or B and C, or A, B, and C.

It should be noted that the term “a plurality of” as used in embodiments of this disclosure refer to two or more.

In embodiments of this disclosure, relational terms such as “first,” “second,” etc., are used solely to distinguish one entity or operation from another, and do not require or imply any actual relationship or sequence between these entities or operations. Additionally, words such as “include,” “have,” “contain,” and other similar forms are intended to be equivalent in meaning and open-ended. One or more items following any of these words do not imply an exhaustive list of such items or a limitation to only the listed items.

It should be noted that the sequence numbers of the respective steps in this embodiment do not represent limitations on the execution order of the respective steps.

In the foregoing specification, implementations have been described with reference to numerous specific details that may vary by implementation. Certain changes and modifications may be made to the described embodiments. Considering the specification and practice of the application disclosed herein, other embodiments may be apparent to those skilled in the art. The specification and examples are to be regarded as exemplary only, with the true scope and spirit of the application being indicated by the following claims. The order of steps shown in the drawings is also intended for illustrative purposes only and is not intended to be limited to any particular order of steps. Thus, those skilled in the art may appreciate that these steps may be performed in different orders while achieving the same method.

In the accompanying drawings and specification, exemplary embodiments have been disclosed. However, numerous variations and modifications can be made to these embodiments. Therefore, although specific terms are employed, they are used in a generic and descriptive sense only and not for purposes of limitation.

Although the present disclosure is disclosed as above, it is not limited thereto. Any person skilled in the art can make various changes and modifications without departing from the spirit and scope of the present disclosure. Therefore, the protection scope of the present disclosure should be subject to the scope defined by the claims.

What is claimed is:

1. A method for forming a semiconductor structure, comprising:
providing a substrate having a metal gate trench, wherein a bottom and sidewalls of the metal gate trench are provided with a work function layer;
forming a diffusion barrier layer on the work function layer, comprising:
forming a first diffusion barrier sublayer via a physical vapor deposition process with a negative bias power less than a preset power on the work function layer at the bottom of the metal gate trench; and
forming a second diffusion barrier sublayer covering the sidewalls of the metal gate trench and the first diffusion barrier sublayer.

2. The method according to claim 1, wherein the preset power is less than or equal to 100 W.

3. The method according to claim 1, wherein forming the first diffusion barrier sublayer layer further comprises: applying nitrogen gas at a first gas flow rate in the physical vapor deposition process to form the first diffusion barrier sublayer comprising a first nitride material; and
wherein the forming the second diffusion barrier sublayer comprises:
reducing the first gas flow rate to a second gas flow rate to form the second diffusion barrier sublayer comprising a second nitride material.

4. The method according to claim 1, wherein the forming the second diffusion barrier sublayer further comprises: performing a physical vapor deposition process with a negative bias power selected from a range of 200 W to 600 W.

5. The method according to claim 3, wherein the first gas flow rate is greater than the nitrogen flow rate corresponding to a minimum point determined by a relationship curve, and the second gas flow rate is less than the nitrogen flow rate corresponding to an inflection point determined by the relationship curve;
wherein the relationship curve comprises a first curve and a second curve, the first curve reflecting a first voltage corresponding to the nitrogen flow rate increased from zero to a preset value, and the second curve reflecting a second voltage corresponding to the nitrogen flow rate decreased from the preset value to zero;
the inflection point is a point corresponding to the change of the voltage in the first curve from a tendency to decrease to a tendency to increase;
the minimum point is greater than the inflection point, and the minimum point is a point at which the voltage is minimum among overlap points of the first curve and the second curve.

6. The method according to claim 3, wherein:
the first gas flow rate is selected from a range of 80 sccm to 120 sccm; and/or,
the second gas flow rate is selected from a range of 20 sccm to 40 sccm.

7. The method according to claim 3, further comprising:
forming a wetting layer on the second diffusion barrier sublayer on the sidewalls and the bottom of the metal gate trench;
filling a metal material into the metal gate trench.

8. The method according to claim 7, wherein the wetting layer comprises a titanium layer.

9. The method according to claim 1, wherein a thickness of the first diffusion barrier sublayer covering the sidewalls of the metal gate trench is 0 to 0.5 nm; and a thickness of the first diffusion barrier sublayer covering the bottom of the metal gate trench is 4 nm to 7 nm.

10. The method according to claim 1, wherein a thickness of the first diffusion barrier sublayer at the bottom of the metal gate trench is from 0.6 to 0.7 times a total thickness of the diffusion barrier layer at the bottom of the metal gate trench.

11. A semiconductor structure, comprising:
a substrate having a metal gate trench;
a work function layer covering a bottom and sidewalls of the metal gate trench;
a diffusion barrier layer comprising a first diffusion barrier sublayer and a second diffusion barrier sublayer, wherein the first diffusion barrier sublayer is located on the work function layer at the bottom of the metal gate trench, and the second diffusion barrier sublayer covers the sidewalls of the metal gate trench and the first diffusion barrier sublayer.

12. The semiconductor structure according to claim 11, wherein the first diffusion barrier sublayer comprises a first nitride material and the second diffusion barrier sublayer comprises a second nitride material, and nitrogen content in the first diffusion barrier sublayer is higher than that in the second diffusion barrier sublayer.

13. The semiconductor structure according to claim 12, wherein:
the first diffusion barrier sublayer is a first titanium nitride layer;
and/or the second diffusion barrier sublayer is a second titanium nitride layer.

14. The semiconductor structure according to claim 11, further comprising:
a wetting layer located on the second diffusion barrier sublayer on the sidewalls and the bottom of the metal gate trench;
a metal material filled in the metal gate trench.

15. The semiconductor structure according to claim 14, wherein the wetting layer comprises a titanium layer.

16. The semiconductor structure according to claim 11, wherein a thickness of the first diffusion barrier sublayer covering the sidewalls of the metal gate trench is 0 to 0.5 nm; and/or a thickness of the first diffusion barrier sublayer covering the bottom of the metal gate trench is 4 nm to 7 nm.

17. The semiconductor structure according to claim 11, wherein a thickness of the first diffusion barrier sublayer at the bottom of the metal gate trench is 0.6 to 0.7 times a total thickness of the diffusion barrier layer.

18. A semiconductor device, comprising a metal gate formed in a metal gate trench, and the metal gate comprises:
a work function layer covering a bottom and sidewalls of the metal gate trench; and
a diffusion barrier layer comprising a first diffusion barrier sublayer and a second diffusion barrier sublayer, wherein the first diffusion barrier sublayer is located on the work function layer at the bottom of the metal gate trench, and the second diffusion barrier sublayer covers the sidewalls of the metal gate trench and the first diffusion barrier sublayer.

19. The semiconductor device according to claim 18, wherein:
a thickness of the first diffusion barrier sublayer covering the sidewalls of the metal gate trench is 0 to 0.5 nm; and
a thickness of the first diffusion barrier sublayer covering the bottom of the metal gate trench is 4 nm to 7 nm.

20. The semiconductor device according to claim 18, wherein further comprising:
a wetting layer located on the second diffusion barrier sublayer on the sidewalls and the bottom of the metal gate trench; and
a metal material filled in the metal gate trench.
